(19) United States
(12) Patent Application Publication
(10) Pub. No.: US 2010/0025287 A1
(43) Pub. Date: Feb. 4, 2010

(54) Wafer Container with Constraints

(76) Inventors: Chin-Ming LIN, Shulin City (TW); Kuan-Lun PAN, Shulin City (TW)

Correspondence Address: SINORICA, LLC, 2275 Research Blvd., Suite 500, ROCKVILLE, MD, 20850, US

(21) Appl. No.: 12/187,421

(22) Filed: Aug. 7, 2008

(30) Foreign Application Priority Data
Jul. 31, 2008 (TW) 097128926

(51) Int. Cl. H01L 21/673; B65D 85/86; B65D 85/30

(52) U.S. Cl. 206/711; 206/454; 206/722

(57) ABSTRACT

A wafer container includes a container body that having an open front on sidewall, a plurality of slots disposed in the container body for support wafers, and a door is assembled with opening of the container body for protecting the wafer therein, the characteristic in that: an recess is disposed in the inner surface, and a wafer restraint modules on the sides of the recess. The wafer restraint module includes a base portion for fixing the wafer restraint module on the platform, and a plurality of curve portions is formed on the side of the platform, in which each curve portion and the free ends constructed the protruding portion, thereby, the guiding notch of the protruding portion contacted the wafer to restrict the wafer from moving.

### BACKGROUND OF THE INVENTION

1. Field of the Invention

The present invention is related to a front opening unified pod (FOUP), more particularly to the FOUP including the wafer restraint modules being disposed on two platforms adjacent to the edge of the recess of the door. Thus, the wafer can be disposed within the recess of the door to reduce the size of FOUP, and the wafer restraint component can sustain the wafer to avoid from movement during the wafer transportation procedure.

2. Description of the Prior Art

The semiconductor wafers are transferred to different stations to apply the various processes in the required equipments. A sealed container is provided for automatic transfer to prevent the pollution. FIG. 1 shows the views of wafer container of the conventional prior art. The wafer container is a front opening unified pod (FOUP) which includes a container body 10 and a door 20. The container body 10 is disposed a plurality of slots for placing the plurality of wafers, and an opening 12 is located on the sidewall of the container body 10 for loading or un-loading. Further, the door 20 includes an outer surface 21 and an inner surface 22, in which the door 20 is joined the opening 12 of the container body 10 to protect the plurality of wafers within the container body 10. Furthermore, at least one latch component 23 is disposed on the outer surface 21 of the door 20 for opening or closing the wafer container. According to aforementioned, due to the wafer is placed in the container body 10 in horizontal, thus, the FOUP needs a wafer restraint component to avoid from movement during the wafer transportation. FIG. 2 is a view of a front opening unified pod (FOUP) as described in U.S. Pat. No. 6,736,268. As shown in FIG. 2, the inner surface 22 of the door 20 is disposed with a recess 24 and the recess 24 is extended from the top 221 of the inner surface 22 to the bottom 222, and is located between two locking components 230 (inside of the door 200). The wafer restraint module (not shown in Figure) further includes the recess 24, in which the wafer restraint module consists two wafer restraint components 100, and each wafer restraint component 100 includes a plurality of wafer contact heads 110 to sustain the wafers, so as to prevent the wafer from the movement toward the door opening due to the wafer transportation procedure. However, the wafer restraint module is disposed on the recess 24 of the inner surface 22 of the door 20, and the wafer merely is attached to the inner surface 22 of the door 20 or the wafer is partially settled down within the recess 24. The wafers either sit adjacent to the inner surface 22 of the door 20 or only slightly enter into the recess 24. As resulted, the wafers do not securely and fully settle into the recess 24 in order to effectively shorten the length between the front side and the back side of the FOUP. In addition, the tiny dust particles generated due to the friction between the wafer restraint module and the wafers can be easily accumulated in the recess 24. In the process of cleaning the accumulated dust particles, it is necessary to separate the wafer restraint module from the recess 24 on the inner surface 22 of the door 20. By frequently separation and assembly of the wafer restraint module due to the cleaning process, the wafer restraint module is easily slackened.

### SUMMARY OF THE INVENTION

According to the drawbacks of the aforementioned, the present invention provides a front opening unified pod (FOUP) with wafer restraint modules disposed on two platforms and adjacent to the edge of the recess of the door. The wafers can thus fully, and effectively be filled in the space of the recess. This makes shortening the length between the front side and the back side of the FOUP be possible.

The other objective of the present invention is to provide a front opening unified pod (FOUP) with wafer restraint modules, which are disposed on the platforms of the two sides of the recess. With such the space where the end of wafer supported in the restraint module is shortened. As results, not only the door shuts tightly and smoothly, but also the dust particles generated during the wafer transportation can be significantly reduced.

The other objective of the present invention is to provide a front opening unified pod (FOUP) with wafer restraint module, where the wafer restraint modules are disposed on the platforms of the two sides of the recess. With such, the tiny dust particles generated due to the friction between the wafer restraint module and wafer can drop and be collected at the corners the recess. When cleaning the FOUP, it becomes easy in cleaning the dust particles without removing the wafer restraint module.

The yet objective of present invention is to provide a front opening unified pod (FOUP) with a wafer restraint module. The wafer restraint module is formed as a bent arm component, which has a plurality of end-points to sustain the wafer firmly to reduce the dust particles that are generated due to the vibration during the transportation of front opening unified pod.

According to above objectives, the present invention provides a wafer container with a wafer restraint module, which includes a container body, and a door. The inner surface of the container body includes a plurality of slots for sustain a plurality of wafers therein; a side-wall of the container body includes an opening for exporting or importing wafers; the inner surface of the door is disposed in a recess, in which the recess is located between the two platforms. Further, each wafer restraint module is disposed on two platforms and located adjacent to the inner surface of the door, and the wafer restraint module includes a base portion to fix the wafer restraint modules on the platforms. Herein, there is a plurality of curve portions with each spaced one another and formed on the longer side of the base portion which are shaped in by various length of sides, and each curve portions constructed the free-end to form a semicircle-like protruding portion. Thus, the guide notch of the semicircle-like protruding portion is contacted the wafer to restrict the wafer that is moved toward the opening of the front opening unified pod (FOUP).

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a sectional view of the wafer container of the prior art;

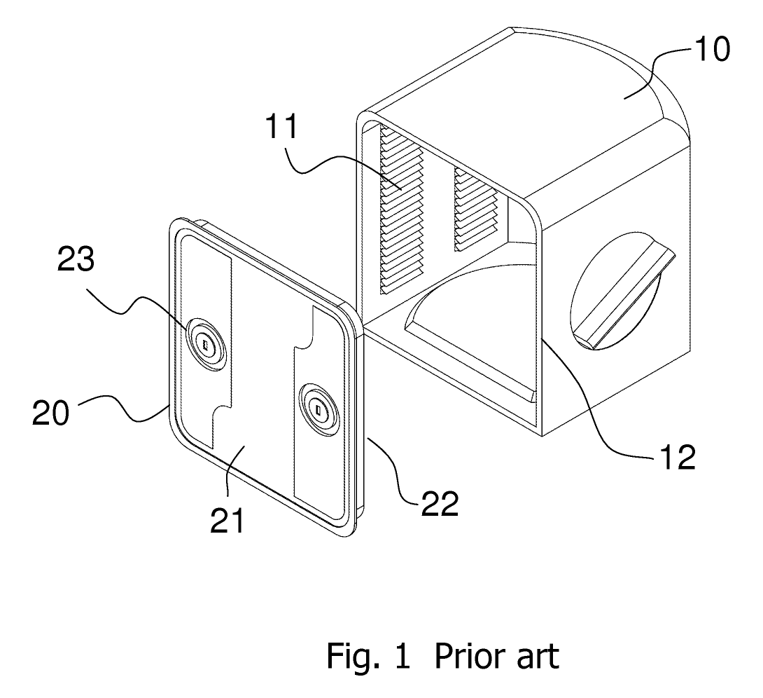

FIG. 2 is a sectional view of the wafer restraint component of the prior art;

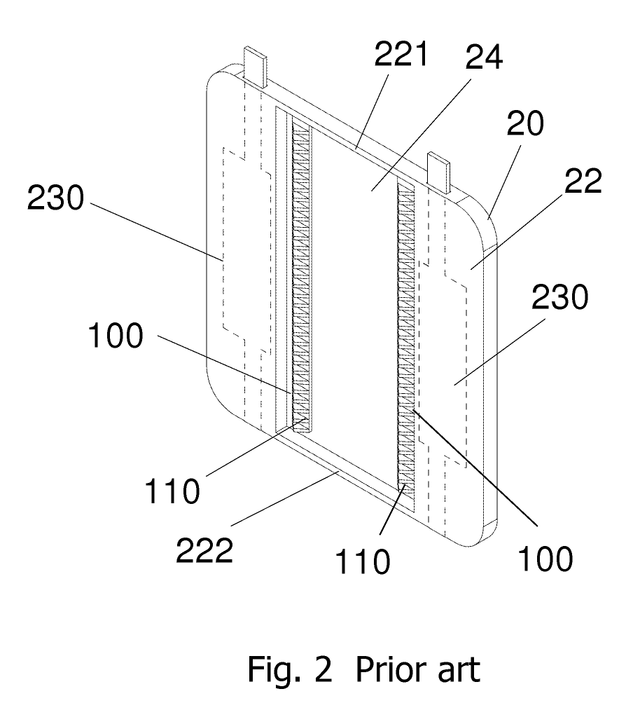

FIG. 3 is a view of the wafer container of the first embodiment of the present invention;

FIG. 4 is a view of the wafer restraint module of the wafer container of the first embodiment of the present invention;

FIG. 5 is a view of the wafer restraint module fixed on the door of the first embodiment of the present invention;

FIG. 6 is a view of the wafer restraint module to restrict the wafer of the first embodiment of the present invention;

FIG. 7A is a view of the two wafer restraint module is an integrated structure of the wafer container of the first embodiment of the present invention;

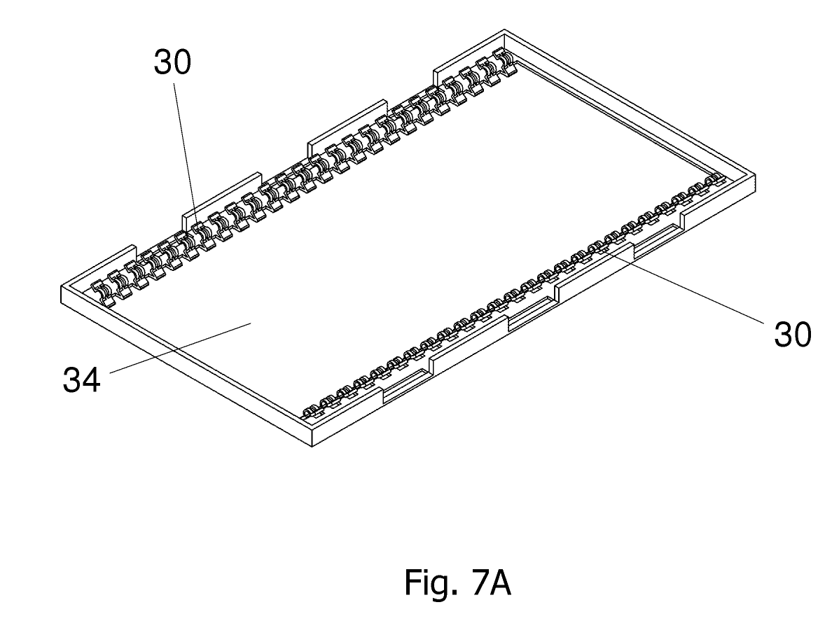

FIG. 7B is a view of the two wafer restraint module is integrated with the door of the first embodiment of the present invention;

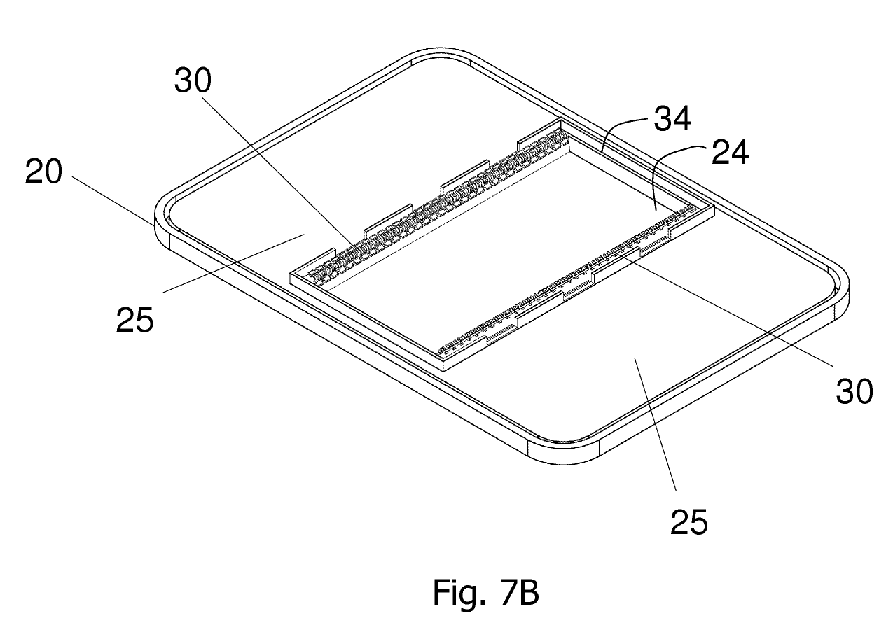

FIG. 8 is a view of the another wafer container of second embodiment of the present invention;

FIG. 9 is a view of the wafer restraint module of the another wafer container of the second embodiment of the present invention;

FIG. 10A is a view of a wafer restraint component that is not contact the wafer of the second embodiment of the present invention;

FIG. 10B is a view of the wafer restraint module to restrict the wafer of the second embodiment of the present invention;

FIG. 11 is a view of the wafer container of the third embodiment of the present invention;

FIG. 12 is a view of the wafer restraint module of the wafer container of the third embodiment of the present invention;

FIG. 13A is a view of a wafer restraint component that is not contact the wafer of the third embodiment of the present invention; and

FIG. 13B is a view of the wafer restraint module to restrict the wafer of the second embodiment of the present invention.

### DESCRIPTION OF THE PREFERRED EMBODIMENT

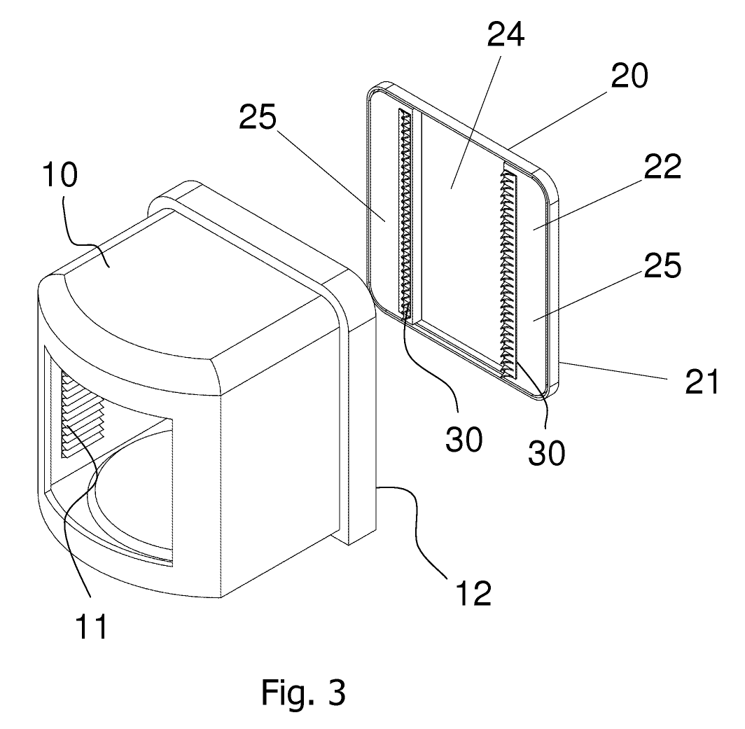

Referring to FIG. 3 shows a view of the wafer container of the first embodiment. The wafer container is a front opening unified pod (FOUP) which includes a container body 10 and a door 20. a plurality of slots 11 is disposed in the inside of the container body 10 to place a plurality of wafers therein, and an opening is located on one of sidewalls of the container body 10 that is provided for loading or exporting or importing of wafer. The doors 20 includes an outer surface 21 and an inner surface 22, in which at least one latch component (not shown) is disposed on the outer surface 21 for opening or closing the front opening unified pod. A recess 24 is disposed on the center portion of the inner surface 22 of the door 20, in which the recess is located between two platforms 25. The wafer restraint used to support the plurality of the wafers within the container body 10 to reduce the size of the wafer container. Furthermore, each wafer restraint module 40 is disposed on the platform adjacent to the edge of recess to restrict the wafer from moving toward the opening of the wafer container, and the number of the wafers is settled down the recess that can be controlled. Furthermore, each two platforms is provided to have a latch component (not shown in Figure) thereon, and a latch opening 23 is formed on the outer surface 21 corresponding to each latch component.

The length of the recess 24 of the inner surface 22 of the door is related to the distance of the slots 11 of the container body 10 and the number of the wafers. For example, the distances between the 12″ or 18″ wafers have been a standard regulation in the industry to obtain the maximum ability of loading and the space is enough to contain the arm to export or import. In general, the number of wafers for the wafer container is 25 pieces. Thus, the length of the recess 24 is constant. However, the width and the depth of the recess 24 of this embodiment can be adjusted. When the width of the door 20 is constant, the depth of the recess 24 can be adjusted to deeper, and the width of recess 24 is also adjusted to wider, so as the whole wafer can place within the recess 24.

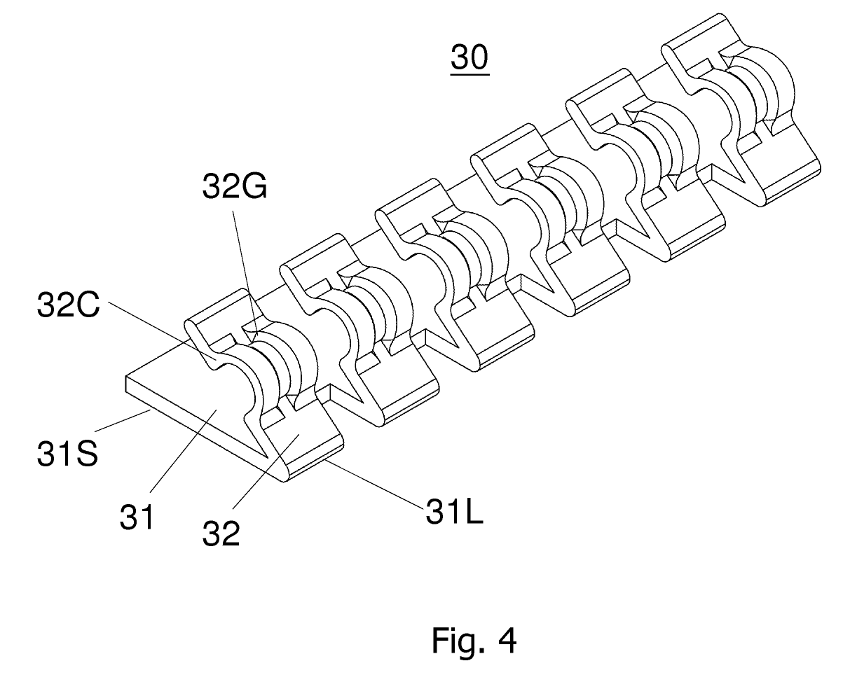

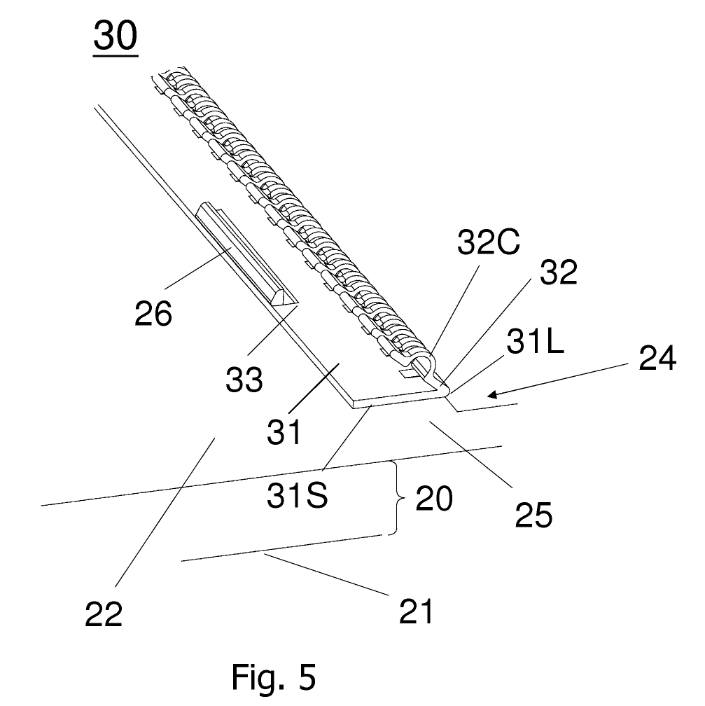

Moreover, referring to FIG. 4 and FIG. 5, show the views of the wafer restraint module of the wafer container and fixed on the door. The wafer restraint module 30 is a rectangle bar base portion 31, which includes two longer sides 31L and two shorter sides 31S. One of two loner sides 31L is adjacent the recess 24 to form a plurality of curve portions 32 with a spaced at interval. Each curve portions 32 and the free-ends are constructed to form a semicircle-like protruding portion 32C. The guide notch 32G is disposed on the semicircle-like protruding portion 32C to contact the wafer to restrict the wafer from moving toward the opening of the wafer container.

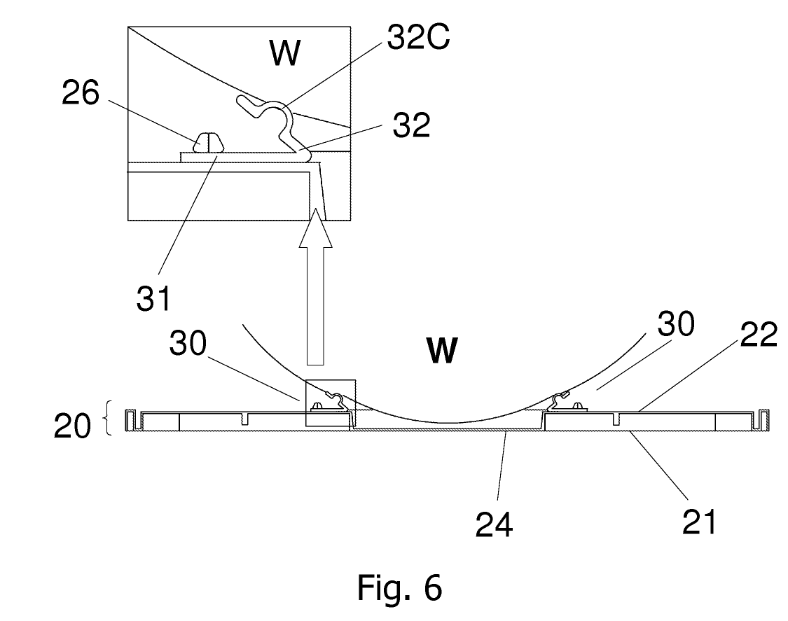

The guide notch 32G of the semicircle-like protruding portion 32C used to sustain the wafer, in which the width of the guide notch 32G is equaled to the thickness of the wafer, so that the wafer can sink into the guide notch 32G to avoid the movement for the wafer. The contacted surface between the guide notch 32G and the wafer can be coated a wear-resisting material, such as PEEK material, to reduce the friction for the wafer. Furthermore, the wafer restraint module 30 can be an integrated structure, and is made of one or two different materials. For example, the base portion 31 and the curve portion 32 are made of one material, and the semicircle protruding portion 32C is made of another material and formed on the curve portion 32. Obviously, the an included angle is located between the base portion 31 with rectangle bar shaped and the curve portion 32, in which the angle is about 10 to 60 degree. The resultant forces is formed toward the central of the wafer when the wafer is restricted by the wafer restraint module (as shown in FIG. 6), and the wafer would not shaken due to the wafer restraint module 30 on two sides of the recess 24 is symmetrical. In addition, the wafer restraint module 30 not only restricts the wafer from moving toward the opening of the wafer container, and the wafer can sink into the recess 24, so that the length of front side and back side can be reduced. As shown in FIG. 4, due to a gap is located between the plurality of semicircle protruding portion 32C on the curve portion 32, thus, the curve portion 32 is elasticity to permit the deformed by crackdown of the wafer.

Furthermore, according to the FIG. 5 and FIG. 6, the base portion 31 includes a plurality of snap holes 33, and a snap pillar 26 is disposed on the inner surface 22 that corresponding to the snap holes 33, thus, the wafer restraint module 30 is firmly on the platforms 25 of the recess 24 of the inner surface 22 of the door 20 by snapping on. For the manufacturing, the wafer restraint module 30 is integrated with the inner surface 22 of door 20 to prevent the slack of the wafer restraint module 30. The integrated structure includes a central hole 34 that corresponding to the recess 24, so that the integrated structure is firmly on the inner surface 22 by snapping on or integrated with the inner surface 22 of the door 20 directly.

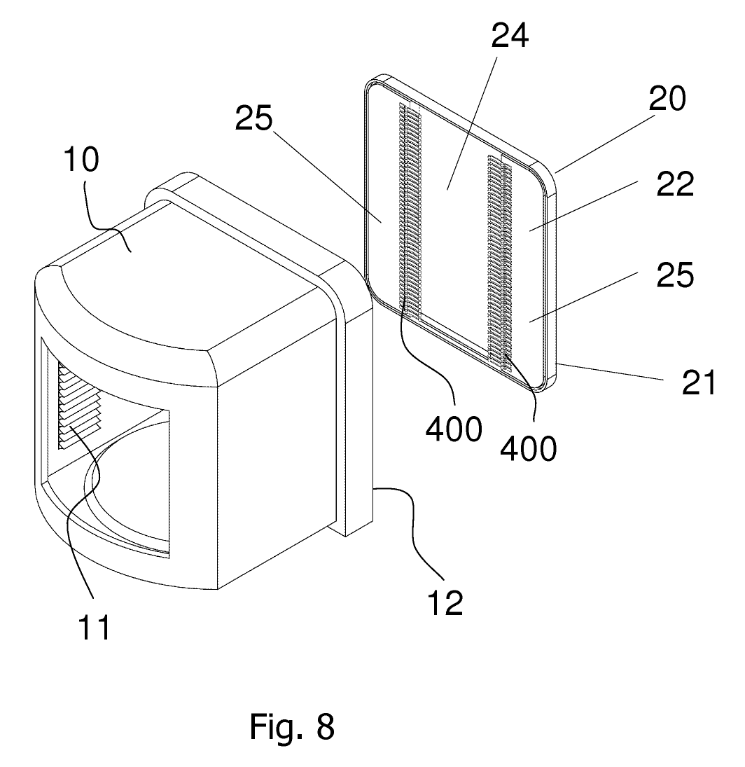

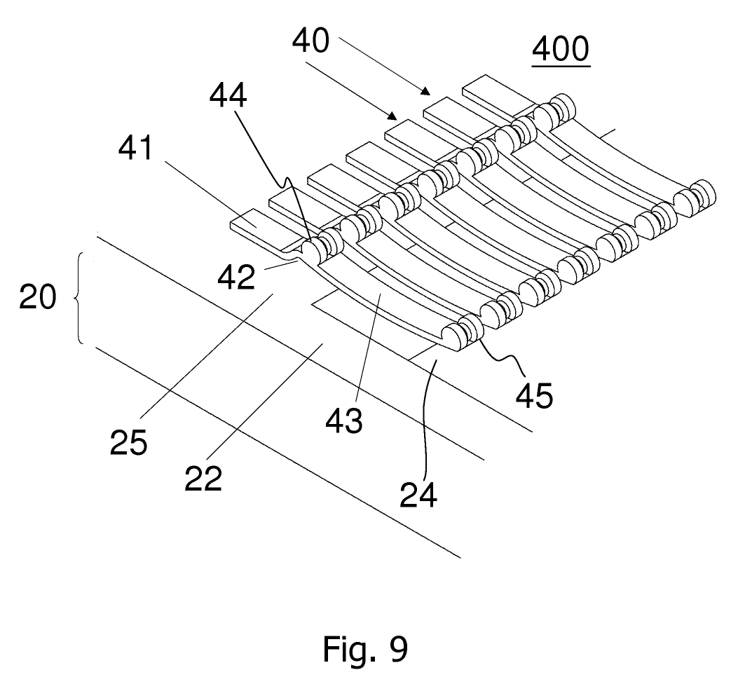

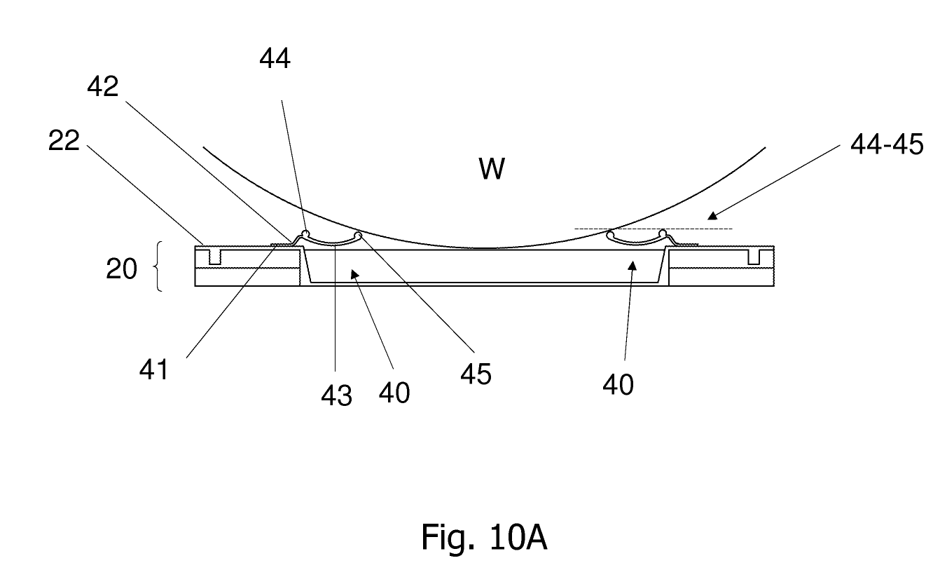

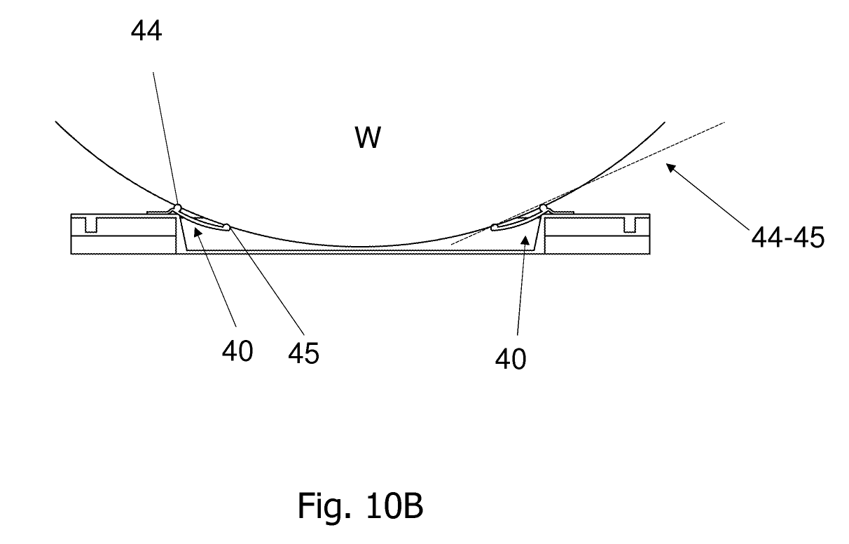

Secondly, FIG. 8 shows a view of another wafer container of the second embodiment of this invention. The wafer container is same as the wafer container of the first embodiment, which includes a container body 10 and a door 20. The different between the second embodiment and the first embodiment is that the wafer restraint module 400 is fixed on two sides of the recess 24 of the inner surface 22 of the door 20. As shown in FIG. 9 and FIG. 10, the wafer restraint module 400 on two sides of the recess 24 are formed by a plurality of wafer restraint components 40 with a spaced at interval, and each wafer restraint components aligned the another wafer restraint module 40 on the wafer restraint module 400 that is located on one side of the recess. Each wafer restraint components 40 include a base portion 41 which fixed on the inner surface 22 of the door 20, and one side of the base portion 41 is located adjacent to the recess 24. The sidewall is extended toward the opening of the container body 10 to form a curve portion 42 and taken to turn the central portion of the recess 24 to form a plurality of bent arms 43. The plurality of bent arms is disposed on two side of the top of the recess 24, and the cross of the bent arm 43 and the curve portion 42 include a first contact head 44, and the free-end of the bent arm 43 includes a second contact head 45 thereon. As shown in FIG. 10, each wafer restraint components 40 is an elastic integrated structure (for example: thermal-elastic plastic). When the door 20 and the container body 10 will be jointed, the connected line between the first contact head 44 and the second contact head 45 of the wafer restraint component 40 is paralleled to the inner surface 22 of the door 20. Meanwhile, the wafer is contacted to the second contact head 45 to deform the curve portion 42 to drive the bent arm 43, so as the first contact head 44 will contact the wafer in sequence. Referring to FIG. 10B, the door 20 is sealed with the container body 10, and an included angle is formed between the connected line of the first contact head 44 and the second contact head 45 of the wafer restraint component 40 and the inner surface 22 of the door 20. Obviously, each wafer restraint components 40 used to contact the wafer by two contact head (44 and 45) to sustain the wafer or restrict the wafer from moving toward to the opening of the wafer container. Also, the wafer can sink into the recess 24 to decrease the length of the front side and the back side of the wafer container. In addition, the wafer restraint component 40 is an elastic component which has capability of shockproof to avoid the suddenly vibrated during the wafer transportation.

The curve portion 42 of the wafer restraint component 40 is an elastic structure (for example: thermal-elastic plastic) with a bent angle. Thus, sealing procedure of the door 20 and the container body 10 the bent angle would be changed to make the first contact head 44 that contacted the second contact head 45. Furthermore, the bent portion 42 and the bent arm are made of different two materials, such as plastic with different hardness which can generate the deformation for the curve portion 42 and the bent arm would not deformed easily. The first contact head 44 and the second contact head 45 include a recess respectively, so as the wafer can sink into the recess to avoid the movement of the wafer. Moreover, the plurality of wafer restraint components 40 can form a base portion, in which the base portion is disposed on the inner surface 22 of the door 20 firmly. Certainly, the plurality of wafer restraint components 40 is integrated with the inner surface 22 of the door 29 to reduce the manufacturing cost.

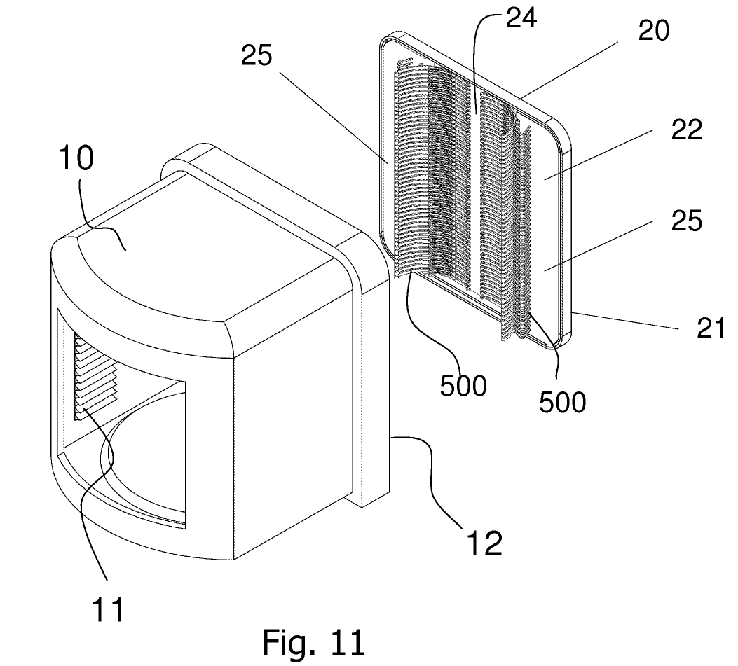

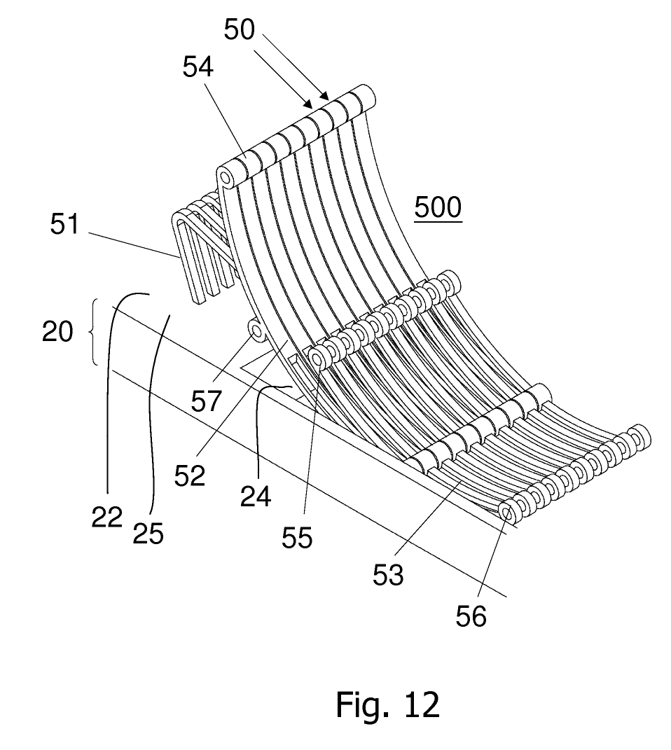

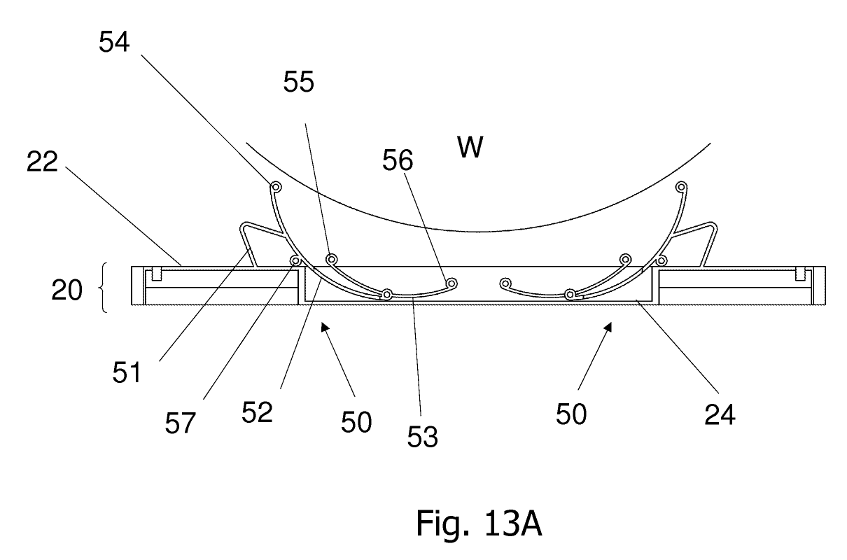

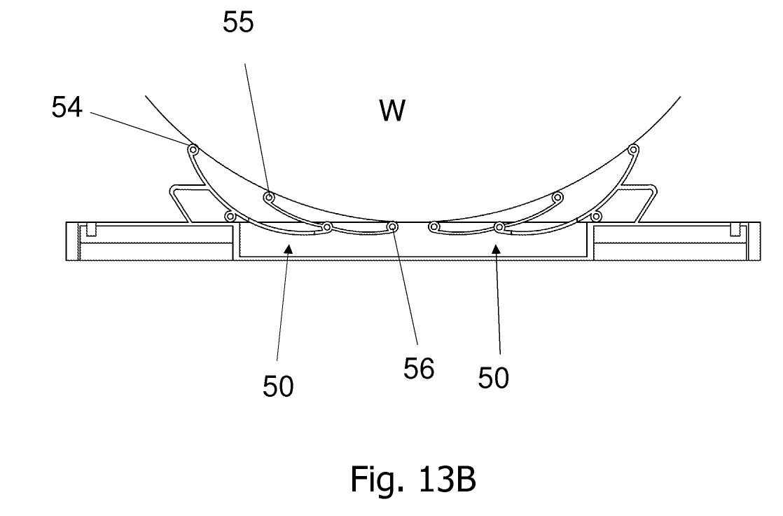

Then, referring to FIG. 11 shows a view of the wafer container of third embodiment of this invention. The apparatus is similar to the wafer container of the second embodiment. The wafer container includes a container body 10 and a door 20. The different is that each wafer container modules 500 is located on two sides of the recess 24 of the inner surface 22 of the door 20 that includes three contact heads, as shown in FIG. 12 and FIG. 13A. The wafer restraint module 50 is located on the two sides of platforms and is arranged by the plurality of wafer restraint components 50. Each wafer restraint components 50 is aligned the wafer restraint component 40 on the wafer restraint module 500 on one side of the recess 24, in which each wafer restraint components 50 include a base portion 51. The one end of the base portion 51 is located on the inner surface 22 of the door 20, and another end is connected to the first bent arm 52, in which the first bent arm includes two free-ends. One of free-ends is located far from the central of the recess 24 that is formed a first contact head 54; another free-end adjacent the central of the recess 24 that contact the second bent arm, and the second bent arm further includes a second contact head 55 and the third contact head 56.

Because the wafer restraint component 50 and the base potion 51 are elastic structure (for example: thermal-elastic plastic structure), includes a bent portion. When the door 20 would be joined with the container body 10, the second bent arm 53 of the wafer restraint component 50 is attached on the surface of the recess 24 in horizontal or suspended on the surface of the recess 24. Thus, the wafer is contacted the first contact head 54 to deform the base portion 51, so as to the included angle of the bent angle would be changed and levered the second contact head 55 and the third contact head 56 to contact the wafer. As showing FIG. 13B, the door 20 is sealed the container body 10, the second bent arm 53 that is far away from the surface of the recess 24 by driven the second contact arm 53. Thus, the restraint body 20 and the wafer contact head 54, the second contact head 55, and the third contact head 56 are contacted the wafer. Obviously, each wafer restraint components 50 include three contact heads for supporting the wafer to restrict the wafer from moving toward the opening of the wafer container. In this embodiment, a pivot 57 is alternatively provided between the two free-ends of the first bent arm 52 and on one side of the inner surface 22 of the door 20, in which the pivot 57 is fixed on the inner surface 22 of door. Thus, when the base portion 51 is deformed or the angle of the curve portion is changed, the first bent arm 52 and second bent arm 53 can be driven so as to the first contact head 54, second contact head 55, and third contact head 56 can attach to the wafer tightly.

According to the abovementioned, each plurality of wafer restraint components 50 can be an elastic integrated structure (for example: thermal-elastic plastic structure). The base portion 51 and the first bent arm 52 or second bent arm 53 also can be made of different materials, or different elastic structure (for example, thermal-elastic structure), such as plastic with different hardness. Thus, bent arm would not be deformed easily due to the deformation of the base portion 51. Alternatively, the first contact head 54, second contact head 55, and third contact head 56 include a recess so as to the wafer is sunk into the recess to restrict the wafer from moving. The plurality of wafer restraint components 50 is formed on the base portion 51, and the base portion is disposed on the inner surface 22 of the door 20. Alternatively, the plurality of wafer restraint components 50 is integrated with the inner surface 22 of the door 20.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A wafer container including a container body that having a plurality of slots therein for placing a plurality of wafers; an opening, is formed on a sidewall of said wafer container for exporting said plurality of wafers or importing said plurality of wafers; and a door including an outer surface and an inner surface, wherein said inner surface of said door is joined with said opening of said container body for protecting said plurality of wafers therein, the characteristic in that:
a recess is disposed on said inner surface of said door and located between two platforms, and each restraint modules is disposed on said two platforms and adjacent to said inner surface of said door, said restraint module including a base portion to fix said restraint module on said two platforms; a plurality of curve portions with a spaced at interval is formed on a longer side of said base portion, each said curve portions and a free-end is formed a semicircle-like protruding portion; and a guide notch is disposed on each said semicircle protruding portion of each said wafer restraint modules, so as to said guide notch of said semicircle-like protruding portion contacted said wafers.

2. The wafer container according to claim 1, wherein each said restraint module is an integrated structure.

3. The wafer container according to claim 1, wherein said restraint module of two sides of said recess is an integrated structure.

4. The wafer container according to claim 3, wherein said two integrated restraint modules include a central hole corresponding to said recess of said door.

5. The wafer container according to claim 1, wherein said restraint module is integrated with said inner surface of the said container body.

6. The wafer container according to claim 1, wherein a wear-resisting material is located on the contact surface between said guide notch of said protruding portion and said wafer.

7. The wafer container according to claim 6, wherein the material of said wear-resisting material is PEEK material.

8. The wafer container according to claim 1, wherein the width of said guide notch of said protruding portion is same as the thickness of said wafer to restrict said wafer from moving.

9. The wafer container according to claim 1, wherein an included angle is located between said base portion and said curve portion.

10. The wafer container according to claim 9, wherein said included angle is about 10 to 60 degree.

11. The wafer container according to claim 1, wherein said base portion of said restraint module includes a plurality of snap holes to snap said restraint module on said platforms.

12. The wafer container according to claim 1, wherein said inner surface of said door correspond to said plurality of snap holes includes a snap pillar to wedge said restraint module on said platforms.

13. The wafer container according to claim 1, wherein said outer surface includes at least a latch component.

14. A wafer container including a container body that having a plurality of slots therein for placing a plurality of wafers, an opening is formed on a sidewall on said container body for exporting said plurality of wafers or importing said plurality of wafers, and a door having an outer surface and an inner surface, said inner surface of said door is assembled with said opening of said container body for protecting said plurality of wafers in said container body, the characteristic in that:
a recess, is disposed on said inner surface of said door and located between said two platforms, and two restraint modules are disposed on said two platforms respectively, each said restraint module is consisted of a plurality of restraint components with a spaced at interval, and one restraint component aligned said restraint component of said restraint module on another edge of said recess, wherein said restraint component includes a base portion, and fixed on said inner surface of said door, and said base portion adjacent one sidewall of said recess, and connected a curve portion, and said curve portion is extended to a central portion of said recess to form a bent arm, wherein said bent arm is disposed on the top of said recess.

15. The wafer container according to claim 14, wherein said restraint module is an integrated structure.

16. The wafer container according to claim 14, wherein said restraint module is integrated with said inner surface of said door.

17. The wafer container according to claim 14, wherein each said restraint module is an integrated structure.

18. The wafer container according to claim 14, wherein each restraint component is integrated with said inner surface of said door.

19. The wafer container according to claim 14, wherein said restraint component is an elastic component.

20. The wafer container according to claim 14, wherein said restraint component is a thermoplastic elastomer.

21. The wafer container according to claim 14, wherein said curve portion of said restraint component is an elastic component.

22. The wafer container according to claim 14, wherein said curve portion of said restraint component is a thermal-elastic component.

23. The wafer container according to claim 14, wherein the materials is different between said curve portion of said restraint component and said bent arm.

24. The wafer container according to claim 14, wherein the elastic materials is different between said curve portion of said restraint component and said bent arm.

25. The wafer container according to claim 14, wherein a crisscross portion between said bent arm and said curve portion is a first contact head, and said free-end of said bent arm is a second contact head.

26. The wafer container according to claim 25, wherein said first contact head and said second contact head include a recess respectively to restrict the from movement during said wafer transportation.

27. The wafer container according to claim 25, wherein a connecting line between said first contact head and said second contact head is paralleled to said inner surface of said door when said door is not joined with said container body.

28. The wafer container according to claim 25, wherein an included angle is formed between said connecting line between said first contact head and said second contact head of said restraint component and said inner surface of said door when said door is joined with said container body.

29. The wafer container according to claim 25, wherein said curve portion of said restraint component is deformed to make said second contact head and said first contact head contact said wafer.

30. The wafer container according to claim 25, wherein said wafer is contacted said second contact head to deform said curve portion so that said first contact head is contacted said wafer.

31. The wafer container according to claim 25, wherein said wafer contacted said second contact head to deform said curve portion and drive said bent arm to cause said wafer contacted said first contact head.

32. The wafer container according to claim 25, wherein said curve portion of said restraint component includes at least a curved angle.

33. The wafer container according to claim 32, wherein said curved angle of said curve portion is changed to cause said first contact head and said second contact head contacted said wafer.

34. The wafer container according to claim 32, wherein said wafer contacted said second contact head to change said curved angle of said curve portion to cause said first contact head contacted said wafer.

35. The wafer container according to claim 32, wherein said wafer contacted said second contact head to change said curve angle of said curve portion to cause said first contact head contacted said wafer.

36. The wafer container according to claim 14, wherein said outer surface includes at least a latch component.

37. A wafer container including a container body that having a plurality of slots for placing a plurality of wafers, an opening is formed on a sidewall of said container body for exporting said plurality of wafer or importing said plurality of wafers, and a door having an outer surface and an inner surface, said inner surface of said door is joined with said opening of said container body for protecting said plurality of wafers in said container body, the characteristic in that:
a recess, is disposed on said inner surface of said door and located between said two platforms, two restraint modules are disposed on said two platforms respectively, each said restraint module is consisted of a plurality of restraint components, and one restraint component aligned said restraint component of said restraint module on another edge of said recess, wherein said restraint component includes a base portion, and one end of said base portion is fixed on said inner surface of said door, and another end of said base portion is connected a first bent arm, said first bent arm having a second free-end, and a first contact head is formed far away from said free-end of said central portion of said recess, and anther free-end of said contact head is connected a second bent arm, and said second bent arm includes a second contact head and said third contact head.

38. The wafer container according to claim 37, wherein said first bent arm is disposed between said two free-ends, and a pivot is disposed adjacent to a sidewall of said inner surface.

39. The wafer container according to claim 38, wherein said pivot is fixed on said inner surface of said door.

40. The wafer container according to claim 37, wherein said restraint component is an integrated structure.

41. The wafer container according to claim 37, wherein said restraint module is integrated with said inner surface of said door.

42. The wafer container according to claim 37, wherein said restraint component is an integrated structure.

43. The wafer container according to claim 37, wherein said restraint component is integrated with sad inner surface of said door.

44. The wafer container according to claim 37, wherein said restraint component is an elastic component.

45. The wafer container according to claim 37, wherein said restraint component is a thermoplastic elastomer.

46. The wafer container according to claim 37, where said base portion of said restraint component is an elastic component.

47. The wafer container according to claim 37, wherein said base portion of said restraint component is a thermoplastic elastomer.

48. The wafer container according to claim 37, wherein the materials is different between said base portion of said restraint component and said first bent arm.

49. The wafer container according to claim 37, wherein the materials is different between said base portion of said restraint component and said second bent arm.

50. The wafer container according to claim 37, wherein the plastic materials is different between said base portion of said restraint component and said first bent arm.

51. The wafer container according to claim 37, wherein the plastic said base portion of said restraint component and said second bent arm is different.

52. The wafer container according to claim 37, wherein said first contact head, said second contact head, and said third contact head of said restraint component includes a recess respectively to restrict from the movement during said wafer transportation procedure.

53. The wafer container according to claim 37, wherein the distance of said second bent arm of each said restraint component is adjacent to said recess of said door when said door is not joined said container body; and the distance of said second bent arm of each said restraint component is far away from said recess of said door when said door is joined said container body.

54. The wafer container according to claim 37, wherein said wafer contacted said first contact head to deform said base portion so that said second contact head and said third is contacted head contact said wafer.

55. The wafer container according to claim 37, wherein said wafer contacted to said first contact head to bend said base portion to lever said first bent arm and said second bent arm to cause said second contact head that contacted said wafer.

56. The wafer container according to claim 37, wherein said base portion of said restraint component includes at least a curve portion.

57. The wafer container according to claim 56, wherein said angle is located on said curve portion of said base portion is changed when said wafer is contacted said first contact head, and said second contact head and said third contact head are contacted said wafer respectively.

58. The wafer container according to claim 56, wherein said wafer contacted said first contact head to deform said curve portion and lever said first bent arm and said second bent arm to cause said wafer is contacted said second contact head and said third contact head.

59. The wafer container according to claim 56, wherein said outer surface of said door includes at least a latch component.

60. A wafer container including a container body that having a plurality of slots for placing a plurality of wafers, an opening is formed on a sidewall of said container body for exporting and importing said wafers, and a door having an outer surface and an inner surface, said inner surface of said door is joined with said opening of said container body for protecting said plurality of wafers therein, wherein said wafer container the characteristic in that:
a recess is disposed on said inner surface of said door and said recess is placed between two platforms, each restraint modules are disposed on said platforms respectively to contact said wafers via said restraint module.
